(19) United States
(12) Patent Application Publication
(10) Pub. No.: US 2024/0222941 A1
(43) Pub. Date: Jul. 4, 2024

(54) LIGHT-EMITTING ELEMENT ARRAY, AND MANUFACTURING METHOD OF LIGHT-EMITTING ELEMENT ARRAY

(71) Applicant: SONY SEMICONDUCTOR SOLUTIONS CORPORATION, Kanagawa (JP)

(72) Inventor: Jugo MITOMO, Kumamoto (JP)

(21) Appl. No.: 18/293,434

(22) PCT Filed: Mar. 17, 2022
(86) PCT No.: PCT/JP2022/012391

§ 371 Date: Jan. 30, 2024

(30) Foreign Application Priority Data
Aug. 30, 2021 (JP) 2021-140414

(51) Int. Cl. H01S 5/42; H01S 5/183

(52) U.S. Cl. CPC H01S 5/42; H01S 5/18311; H01S 5/18327

(57) ABSTRACT

A light-emitting element array according to one embodiment of the present disclosure includes: a substrate that has a first face and a second face that oppose each other, a plurality of light-emitting elements arrayed in two-dimension array on the first face at mutually different intervals, each of the light-emitting elements having a mesa form, and recessed sections that are provided around the plurality of light-emitting elements, have the mesa form, and have depths different according to the intervals of the plurality of light-emitting elements adjacent to each other.

### TECHNICAL FIELD

The present disclosure relates to, for example, a light-emitting element array having a plurality of light-emitting elements randomly arrayed in a face, and a manufacturing method of the same.

### BACKGROUND ART

For example, Patent Literature 1 discloses a face light-emitting laser device in which a separate groove that reaches a substrate surface is provided at a position away from a mesa structure, which passivates a lower semiconductor BDR surface exposed by the separate groove, and further which is covered with a dielectric film.

### CITATION LIST

### Patent Literature

PTL 1: Japanese Unexamined Patent Application Publication No. 2014-132692

### SUMMARY OF THE INVENTION

Incidentally, in a case of using a light-emitting element array as, for example, a light source of a distance-measurement unit, it is desirable that a light-emission that is uniform in the face be used.

It is desirable to provide light-emitting element array having a light emission substantially uniform in a face, and a manufacturing method of the above light-emitting element array.

A light-emitting element array according to one embodiment of the present disclosure includes: a substrate that has a first face and a second face that oppose each other; a plurality of light-emitting elements arrayed in two-dimension array on the first face at mutually different intervals, each of the light-emitting elements having a mesa form; and recessed sections that are provided around the plurality of light-emitting elements, have the mesa form, and have depths different according to the intervals of the plurality of light-emitting elements adjacent to each other.

A manufacturing method of a light-emitting element array according to one embodiment of the present disclosure includes: sequentially layering to form, on a substrate, a plurality of compound semiconductor layers included in a light-emitting element; forming, on the compound semiconductor layers, a resist layer that has patterns different in density; and forming, in the compound semiconductor layers, recessed sections that have depths different according to a pattern density of the resist layer by performing, with the resist layer as a mask, a reactive ion etching under a condition of 80° ° C. or less.

The light-emitting element array according to one embodiment of the present disclosure and the manufacturing method of the light-emitting element array according to one embodiment of the present disclosure sequentially layer to form, on the substrate, the plurality of compound semiconductor layers included in the light-emitting element, thereafter, form, on the compound semiconductor layers, the resist layer that has the patterns different in density, and perform, with the resist layer as the mask, the reactive ion etching under a condition of 80° C. or less. This makes it possible that the plurality of light-emitting elements having the mesa form is, on the first face, formed in two-dimension array at the mutually different intervals, and between the plurality of adjacent light-emitting elements, the recessed sections that have depths different according to the intervals of the plurality of adjacent light-emitting elements are formed, thus offsetting the electric resistance difference caused by the arraying density of the plurality of light-emitting elements.

### BRIEF DESCRIPTION OF DRAWING

FIG. 1 is a cross-sectional schematic diagram illustrating one example of a configuration of a light-emitting element array according to a first embodiment of the present disclosure.

FIG. 2 is a plan schematic diagram illustrating one example of the overall configuration of the light-emitting element array illustrated in FIG. 1.

FIG. 3 is a flowchart describing one example of a manufacturing method of the light-emitting element array illustrated in FIG. 1.

FIG. 4A is a cross-sectional schematic diagram describing the manufacturing method of the light-emitting element array illustrated in FIG. 3.

FIG. 4B is a cross-sectional schematic diagram illustrating a configuration, following FIG. 4A.

FIG. 4C is a cross-sectional schematic diagram illustrating the configuration, following FIG. 4B.

FIG. 4D is a cross-sectional schematic diagram illustrating the configuration, following FIG. 4C.

FIG. 4E is a cross-sectional schematic diagram illustrating the configuration, following FIG. 4D.

FIG. 4F is a cross-sectional schematic diagram illustrating the configuration, following FIG. 4E.

FIG. 4G is a cross-sectional schematic diagram illustrating the configuration, following FIG. 4F.

FIG. 4H is a cross-sectional schematic diagram illustrating the configuration, following FIG. 4G.

FIG. 5 is a schematic diagram describing a current expansion in a general light-emitting element array.

FIG. 6 is a cross-sectional schematic diagram illustrating one example of a configuration of a light-emitting element array according to a second embodiment of the present disclosure.

FIG. 7 is a plan schematic diagram illustrating one example of the overall configuration of the light-emitting element array illustrated in FIG. 6.

FIG. 8 is a flowchart describing one example of the manufacturing method of the light-emitting element array illustrated in FIG. 6.

FIG. 9A is a cross-sectional schematic diagram describing the manufacturing method of the light-emitting element array illustrated in FIG. 8.

FIG. 9B is a cross-sectional schematic diagram illustrating the configuration, following FIG. 9A.

FIG. 9C is a cross-sectional schematic diagram illustrating the configuration, following FIG. 9B.

FIG. 10 is a schematic diagram describing a current expansion in the light-emitting element array illustrated in FIG. 6.

FIG. 11 is a cross-sectional schematic diagram illustrating one example of a configuration of a light-emitting element array according to a modification example of the present disclosure.

FIG. 12 is a cross-sectional schematic diagram illustrating another example the configuration of the light-emitting element array according to the modification example of the present disclosure.

FIG. 13 is a block diagram for illustrating one example of a schematic configuration of a distance-measurement unit using an illumination unit provided with the light-emitting element array illustrated in FIG. 1 or the like.

FIG. 14 is a block diagram depicting an example of schematic configuration of a vehicle control system.

FIG. 15 is a diagram of assistance in explaining an example of installation positions of an outside-vehicle information detecting section and an imaging section.

### MODES FOR CARRYING OUT THE INVENTION

Hereafter, an embodiment of the present disclosure will be described in detail, referring to drawings. The following description is one specific example of the present disclosure, and the present disclosure is not limited to the following embodiments. In addition, the present disclosure, concerning array, dimension, dimension ratio, etc., of component elements illustrated in the respective drawing as well, is not limited thereto. Here, the order of the descriptions is as follows.
1. First Embodiment (example of a back face emission-type light-emitting element array having recessed sections that have depths different according to intervals of adjacent light-emitting elements)
2. Second Embodiment (example of a surface emission-type light-emitting element array having recessed sections that have depths different according to the intervals of adjacent light-emitting elements)
3. Modification Examples (example further provided with a current diffusion layer)
4. Applicable Example (example of distance-measurement unit)
5. Applied Example

### 1. First Embodiment

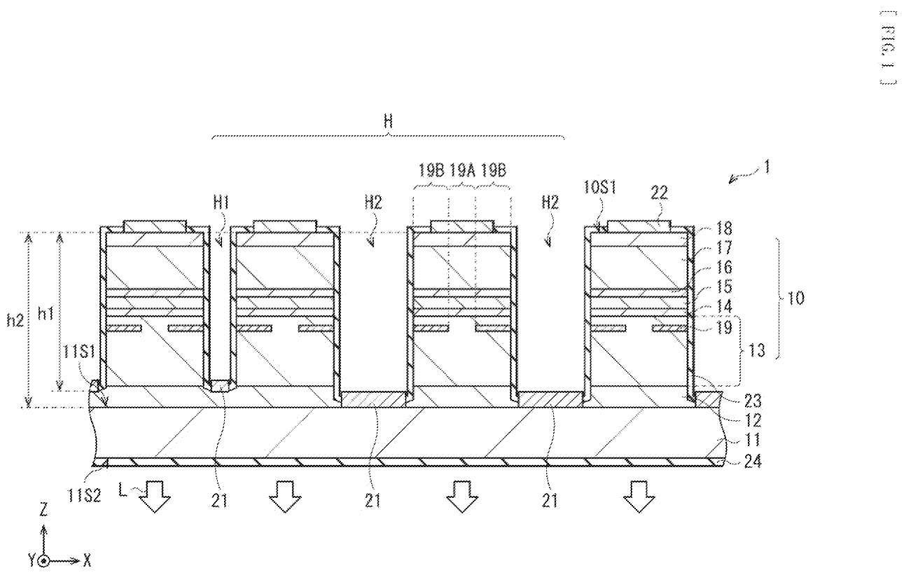

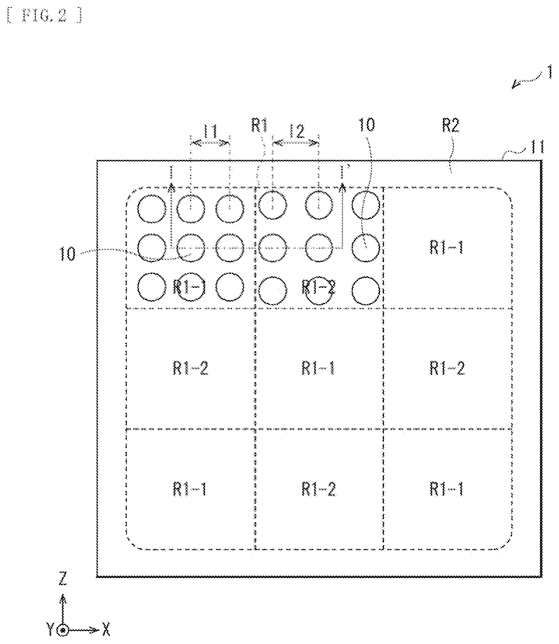

FIG. 1 schematically illustrates one example of a cross-sectional configuration of a light-emitting element array 1 according to a first embodiment of the present disclosure. FIG. 2 schematically illustrates one example of a plan configuration of the overall light-emitting element array 1 illustrated in FIG. 1. FIG. 1 illustrates a cross section that corresponds to the line I-I′ illustrated in FIG. 2. In this light-emitting element array 1, back face emission-type VCSELs (Vertical Cavity Surface Emitting LASERs) are integrated in two-dimension array, for example.

### [Configuration of Light-Emitting Element Array]

In the light-emitting element array 1, a plurality of light-emitting elements 10 is arrayed on a surface 11S1 of a substrate having a first face (surface 11S1) and a second face (back face 11S2) that oppose each other, for example. The light-emitting element array 1 has a light-emission region R1 in which the plurality of light-emitting elements 10 is arrayed in two-dimension array, and a peripheral region R2 provided around the light-emission region R1. The light-emission region R1 corresponds to one specific example of “array section” of the present disclosure.

The plurality of light-emitting elements 10 each has a mesa form. The diameter (mesa diameter) of each of the light-emitting elements 10 is slightly smaller than the smallest beam pitch of laser light outputted from each of the light-emitting elements 10. In a case of making the smallest beam pitch of about 18 μm, for example, the mesa diameter is about 14 μm.

In the light-emitting element array 1 of the present embodiment, the plurality of light-emitting elements 10, in the light-emission region R1, is arrayed at mutually different intervals, for example. For example, in the light-emission region R1, as illustrated in FIG. 2, a first region R1-1 in which the plurality of light-emitting elements 10 is arrayed at a first pitch l1 and a second region R1-2 in which the plurality of light-emitting elements 10 is arrayed at a second pitch l2 are alternately arrayed in a matrix direction. Alternatively, the plurality of light-emitting elements 10 may be so randomly arrayed that, in the light-emission region R1, the intervals of the adjacent light-emitting elements 10 are irregularly different.

In addition, the light-emitting element array 1 has a recessed section H with the plurality of light-emitting elements 10 each in the mesa form. This recessed section H has depths different according to the intervals of the plurality of adjacent light-emitting elements 10. For example, when array pitches (the first pitch l1 and the second pitch l2) of the plurality of light-emitting elements 10 that are respectively arrayed in the first region R1-1 and the second region R1-2 illustrated in FIG. 2 have a relation of l1<l2, a depth h1 of a recessed section H1 provided between the adjacent light-emitting elements 10 in the first region R1-1, and a depth h2 of a recessed section H2 provided between the adjacent light-emitting elements 10 in the second region R1-2 have a relation of h1<h2. That is, the light-emitting element array 1 of the present embodiment is such that, around the plurality of light-emitting elements 10 arrayed at mutually different intervals, there are formed the recessed sections H that are shallower as the intervals of the plurality of adjacent light-emitting elements 10 are narrower, and that are deeper as the intervals of the plurality of adjacent light-emitting elements 10 are wider.

In addition, the first pitch l1 and the second pitch l2 are respectively center-to-center distances of the adjacent light-emitting elements 10 in the first region R1-1 and the second region R1-2.

### [Configuration of Light-Emitting Element]

The plurality of light-emitting elements 10 is the VCSEL that outputs the laser light in the layer direction. In the plurality of light-emitting elements 10, there are sequentially layered a first DBR (Distributed Bragg Reflector) layer 13 including a current confining layer 19 therein, a first spacer layer 14, an active layer 15, a second spacer layer 16, and a second DBR layer 17, for example. Between the plurality of light-emitting elements 10 and a substrate 11, a first contact layer 12 is provided. Upper faces 10S1 of the plurality of light-emitting elements 10 are each provided with a second contact layer 18. Between the plurality of adjacent light-emitting elements 10, in other words, on a base face of the recessed section H (the recessed sections H1 and H2) provided around the plurality of light-emitting elements 10, a first electrode 21 is provided. On the second contact layers 18 provided on the upper faces 10S1 of the plurality of light-emitting elements 10, there are provided second electrodes 22 respectively. In addition, an upper face of the first contact layer 12 excluding the region for forming the first electrode 21 and the second electrode 22, side faces of the plurality of light-emitting elements 10, and the side face and upper face of the second contact layer 18 are covered with an insulative film 23, and the back face 11S2 of the substrate 11 is covered with an anti-reflection film 24.

Hereafter, the configuration, material and the like of each section of the light-emitting element array 1 are to be described in detail.

The substrate 11 is a support substrate in which the plurality of light-emitting elements 10 is integrated. The substrate 11 includes a semi-insulating substrate that transmits light emitted from the plurality of light-emitting elements 10. Examples of the semi-insulating substrate include a substrate that does not include an impurity and that includes a GaAs semiconductor. In addition, the substrate 11 may be any as long as having a low carrier concentration and a decreased laser light absorption, and is not necessarily limited to a general semi-insulating substrate. As the substrate 11, a substrate having an n-type carrier concentration of 5×10¹⁷ cm⁻³ or less may be used, for example.

The first contact layer 12 is used for causing the first electrode 21 to have an ohmic contact with the first DBR layer 13 of each of the light-emitting elements 10. The first contact layers 12, as a common layer to the plurality of light-emitting elements 10, for example, are continuously formed on the surface 11S1 of the substrate 11. The first contact layer 12 includes an n-type Al_{X1}Ga_{1-X1}As (0≤X1<1), for example.

The first DBR layer 13 includes an n-type semiconductor material, for example. The first DBR layer 13, via the active layer 15, opposes the second DBR layer 17, and includes a resonator that causes a light of wavelength λ, which light is generated in the active layer 15, to resonate with the second DBR layer 17 thereby to oscillate the laser. The first DBR layer 13 has such a configuration that a low refractive index layer (not illustrated) and a high refractive index layer (not illustrated) are alternately layered. The low refractive index layer includes, for example, an n-type Al_{X2}Ga_{1-X2}As (0<X2≤1) having an optical film thickness of λ×¼n, and the high refractive index layer includes, for example, an n-type Al_{X3}Ga_{1-X3}As (0≤X3<X2) having an optical film thickness of λ×¼n. λ denotes an oscillation wavelength of laser light emitted from the active layer 15, and n denotes a refractive index.

The current confining layer 19 gives a confining action to the current, and is provided in layer of the first DBR layer 13. The current confining layer 19 has a current injection region 19A and a current confining region 19B. The current injection region 10A is provided in the middle of the current confining layer 19, and the current confining region 19B is provided around the current injection region 19A. The current injection region 19A includes an electrically conductive material, and the current confining region 19B includes an insulative material. Performing an oxidizing from a side face of the light-emitting element 10 having a material included in the current confining layer 19 makes it possible to form the current confining region 19B. The current injection region 19A includes an n-type Al_{X4}Ga_{1-X4}As (0<X4≤1), for example, and the current confining region 19B includes an oxide thereof, for example. In the light-emitting element array 1, providing this current confining layer 19 confines the current caused to be injected from the first electrode 21 to the active layer 15, increasing the current injection efficiency.

The first spacer layer 14 so makes an adjustment that an interval between the first DBR layer 13 and the second DBR layer 17 is 2. The first spacer layer 14 includes an n-type Al_{X5}Ga_{1-X5}As (0≤X5<1), for example.

The active layer 15 emits and amplifies a natural emission light, and a positive hole and an electron that are injected from the first electrode 21 and the second electrode 22 make an emission recombining thereby to generate a stimulated emission light. The active layer 15 has a multilayer quantum well (MQW) structure, for example, in which a plurality of quantum well layers (not illustrated) and a plurality of barrier layers (not illustrated) are alternately layered. The quantum well layer includes In_{X6}Ga_{1-X6}As (0<X6<1), for example, and the barrier layer includes In_{X7}Ga_{1-X7}As (0<X7<X6), for example.

The second spacer layer 16 so makes an adjustment that, together with the first spacer layer 14, the interval between the first DBR layer 13 and the second DBR layer 17 is λ. The second spacer layer 16 includes, for example, a p-type Al_{X8}Ga_{1-X8}As (0≤X8<1).

The second DBR layer 17 includes, a p-type semiconductor material, for example. The second DBR layer 17, via the active layer 15, opposes the first DBR layer 13, and includes a resonator that causes the light of wavelength λ, which light is generated in the active layer 15, to resonate with the first DBR layer 13 thereby to oscillate the laser. The second DBR layer 17, similar to the first DBR layer 13, has such a configuration that the low refractive index layer (not illustrated) and the high refractive index layer (not illustrated) are alternately layered. The low refractive index layer includes, for example, a p-type Al_{X9}Ga_{1-X9}As (0<X9≤1) having an optical film thickness of λ×¼p, and the high refractive index layer includes, for example, a p-type Al_{X10}Ga_{1-X10}As (0≤X10<X9) having an optical film thickness of λ×¼p.

The second contact layer 18 is used for causing the second electrode 22 to have an ohmic contact with the second DBR layer 17 of each of the light-emitting elements 10. The second contact layer 18 includes a GaAs-based semiconductor. The second contact layer 18 includes, for example, an n-type Al_{X11}Ga_{1-X11}As (0≤X11<1).

The first electrode 21 is provided between the plurality of light-emitting elements 10, for example, on the surface 11S1 side of the substrate 11. In other words, the first electrode 21, as a common electrode to the plurality of light-emitting elements 10 arrayed in the form of array in the light-emission region R1, is provided on a base face of the recessed section H provided around the plurality of light-emitting elements 10. The first electrode 21 includes, for example, a multi-layer film of titanium (TI)/platinum (PT)/gold (Au).

The second electrodes 22 are respectively provided on the plurality of light-emitting elements 10, specifically, on the second contact layers 18. The second electrode 22 includes, for example, a multi-layer film of gold-germanium (Au—Ge)/nickel (NI)/gold (Au).

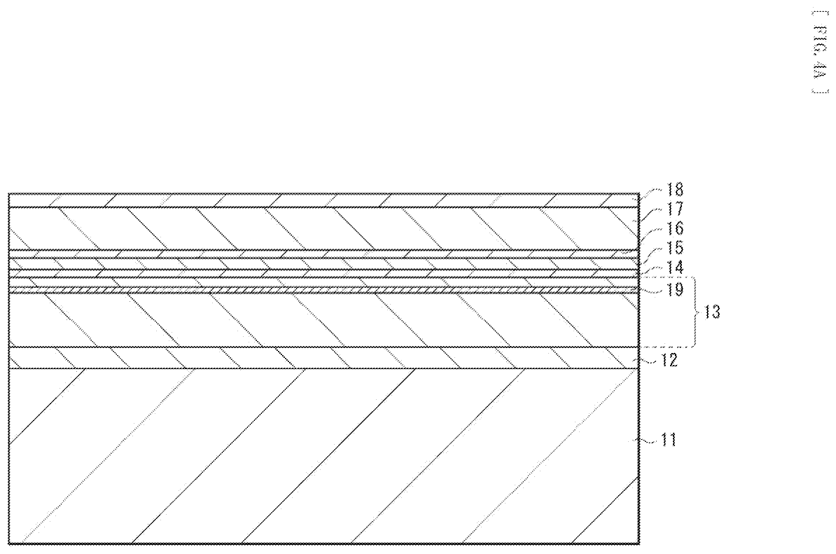

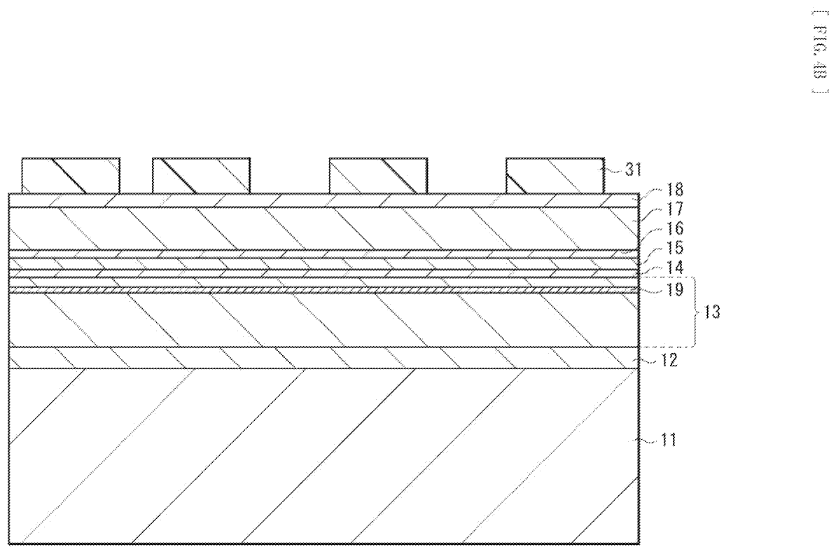

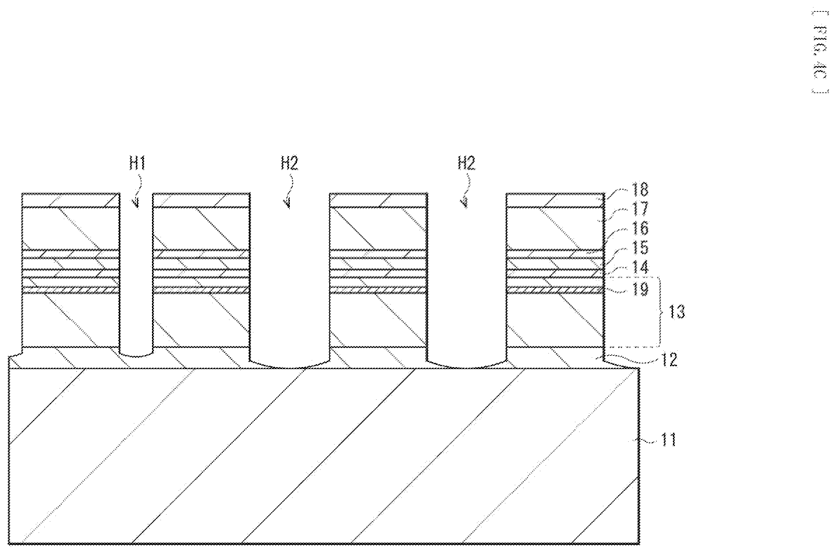

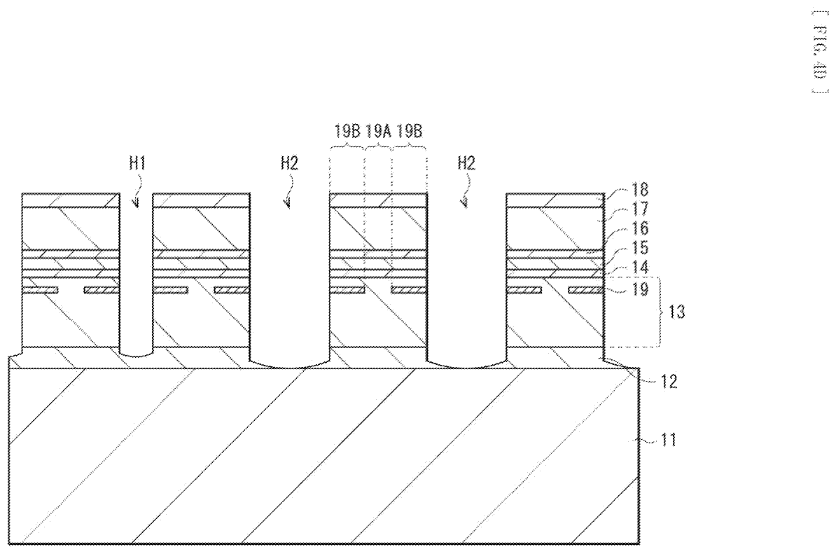

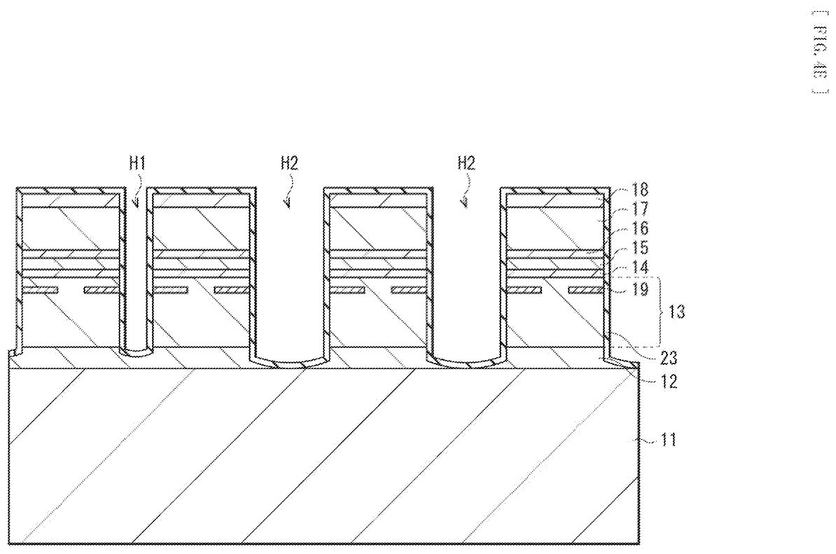

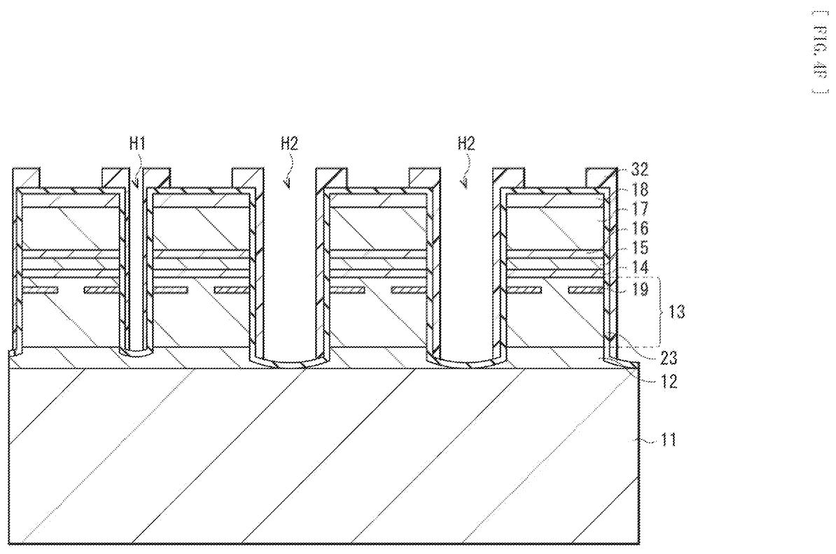

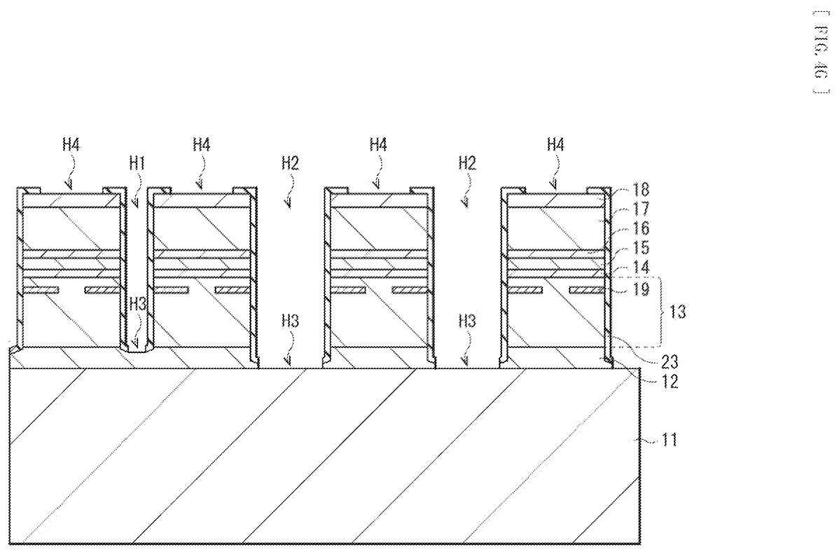

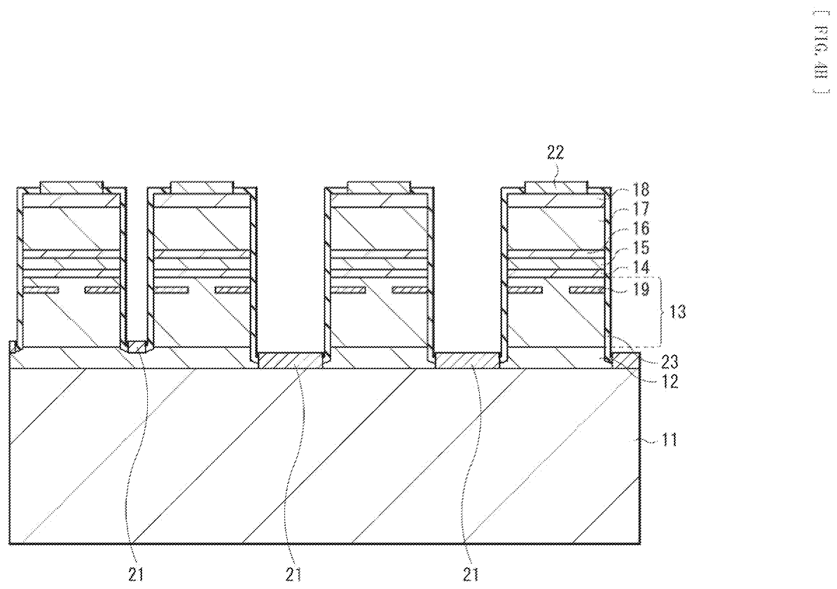

On the upper face of the second contact layer 18, on the side faces of the second contact layer 18 and of the light-emitting element 10, and on the upper face of the first contact layer 12, the insulative film 23 is, for example, continuously formed. The insulative film 23 includes, for example, a single layer film or a laminated film of silicon nitride (SiN), silicon oxide (SiO₂) or the like. At predetermined positions of the insulative film 23 of the first contact layer 12 and of an upper surface of the second contact layer 18, there are respectively provided openings H3 and H4 (for example, refer to FIG. 4G), and the first electrode 21 or the second electrode 22 are respectively embedded in the openings H3 and H4.

The anti-reflection film 24 is formed, for example, on the entire face of the back face 11S2 of the substrate 11. The anti-reflection film 24 includes, for example, a single layer film or a laminated film of silicon nitride (SiN), silicon oxide (SiO₂) or the like.

### [Operation of Light-Emitting Element Array]

The light-emitting element array 1 is so installed that the upper face 10S1 of the light-emitting element 10 faces, for example, a laser driver. In a substrate, the laser driver has, for example, a driver that controls a voltage applied to the light-emitting element array 1. This driver is electrically connected via a wiring line, for example, with the light-emitting element array, generating a drive pulse that causes light emission and light extinction of the plurality of light-emitting elements 10 provided in the light-emitting element array 1.

In the light-emitting element array 1, applying a predetermined voltage from the laser driver to the first electrode 21 and the second electrode 22 respectively applies a voltage to the plurality of light-emitting elements 10 arrayed in two-dimension array. This injects the hole from the first electrode 21 and the electron from the second electrode 22 respectively to the active layer 15, generating light derived from the recombining of the electron and the hole. The light generated in the active layer 15 is resonated between the first DBR layer 13 and the second DBR layer 17 thereby to be amplified, outputting the laser light L from the back face 11S2 of the substrate 11.

### [Manufacturing Method of Light-Emitting Element Array]

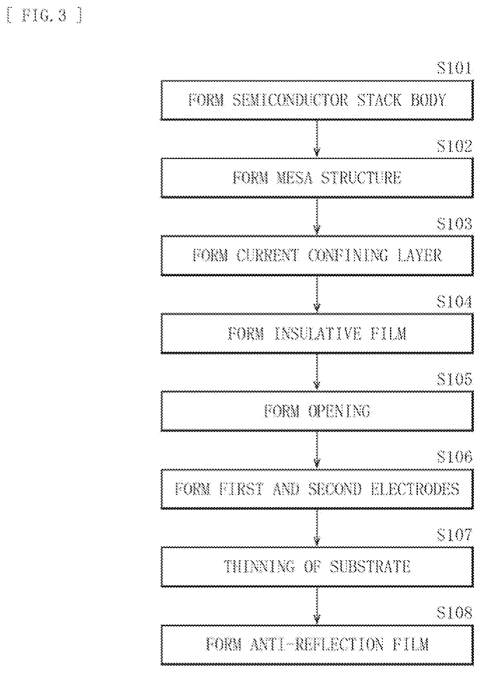

Next, referring to FIG. 3 and FIG. 4A to FIG. 4H, description will be made of a manufacturing method of the light-emitting element array 1.

First, as illustrated in FIG. 4A, on the substrate 11 including GaAs, for example, a compound semiconductor layer (semiconductor laminated body) in which the first contact layer 12, the first DBR layer 13 including the current confining layer 19, the first spacer layer 14, the active layer 15, the second spacer layer 16, the second DBR layer 17, and the second contact layer 18 are sequentially layered is collectively formed by, for example, an epitaxial crystal growth method such as the Metal Organic Chemical Vapor Deposition (MOCVD) method (step S101). In this case, as a raw material of the compound semiconductor, methyl organic metal compounds such as trimethyl aluminum (TMAI), trimethyl gallium (TMGa) or trimethyl indium (TMIn) in combination with arsine (AsH₃) gas is used, as a raw material of a donor impurity, disilane (Si₂H₆) is used, for example, and as a raw material of an acceptor impurity, carbon tetrabromide (CBr₄) is used, for example.

Thereafter, as illustrated in FIG. 4B, resist layers 31 having different density patterns are formed on the second contact layer 18. Thereafter, as illustrated in FIG. 4C, a mesa structure (the light-emitting element 10) is formed by etching the compound semiconductor layer using the resist layer 31 as a mask (step S102). At this time, the reactive ion etching (RIE) by the Cl gas, for example, may be preferably performed on a condition of having increased the micro loading effect. The micro loading effect is a phenomenon in which the mask prevents ion incidence in a section with a dense mask pattern, decreasing the etching rate than in a section with an isolated mask pattern.

Performing the RIE under the condition of having increased this micro loading effect causes a difference in etching rate between the region (for example, the first region R1-1) with the plurality of light-emitting elements 10 densely arrayed, and the region (for example, the second region R1-2) with the plurality of light-emitting elements 10 arrayed in a relatively isolated manner. As described above, between the adjacent light-emitting elements 10 arrayed at the first pitch l1, for example, the recessed section H1 having the base face in the layer of the first contact layer 12 is formed, and between the adjacent light-emitting elements 10 arrayed at the second pitch l2, for example, the recessed section H2 that penetrates the first contact layer 12 is formed. In addition, for increasing the micro loading effect, the RIE may be preferably performed under a condition of 80° C. or less, for example, more preferably, at a room temperature (for example, 25° C.).

Thereafter, after the removing of the resist layer 31, as illustrated in FIG. 4D, the current confining layer 19 is formed by performing a high temperature treatment under a watery vapor atmosphere, for example (step S103). In addition, the wet oxidation method may be used for this oxidizing. This oxidizes an outer peripheral region of the current confining layer 19, forming the current confining region 19B.

Thereafter, as illustrated in FIG. 4E, the insulative film 23 that is continuous from an upper face of the second contact layer 18 to the side faces and base faces of the recessed sections H1 and H2 is formed using the chemical vapor deposition (CVD) method or the atom layer deposition (ALD) method, for example (step S104).

Thereafter, as illustrated in FIG. 4F, a resist layer 32 of a predetermined pattern is formed on the insulative film 23, following which, as illustrated in FIG. 4G, the openings H3 and H4 are formed at predetermined positions of the insulative film 23 by using the RIE, for example (step S105).

Thereafter, as illustrated in FIG. 4H, the first electrode 21 and the second electrode 22 are respectively formed using the lift off technology, for example, that uses the resist pattern (step S106). Thereafter, thinning of the substrate 11 is performed to a predetermined thickness using a back face grinding and a chemical mechanical polishing (CMP), for example (step S107). Thereafter, the anti-reflection film 24 is formed on the back face 11S2 of the substrate 11 using the CVD method or the ALD method, for example (step S108). The above completes the light-emitting element array 1 illustrated in FIG. 1.

### Workings and Effects

The light-emitting element array 1 of the present embodiment is so made as to form, around the plurality of back face emission-type light-emitting elements 10 arrayed in two-dimension array at the mutually different intervals in the light-emission region R1, the recessed sections H (for example, the recessed sections H1 and H2) that have depths different according to the intervals of the plurality of adjacent light-emitting elements 10. In the following, description will be given thereof.

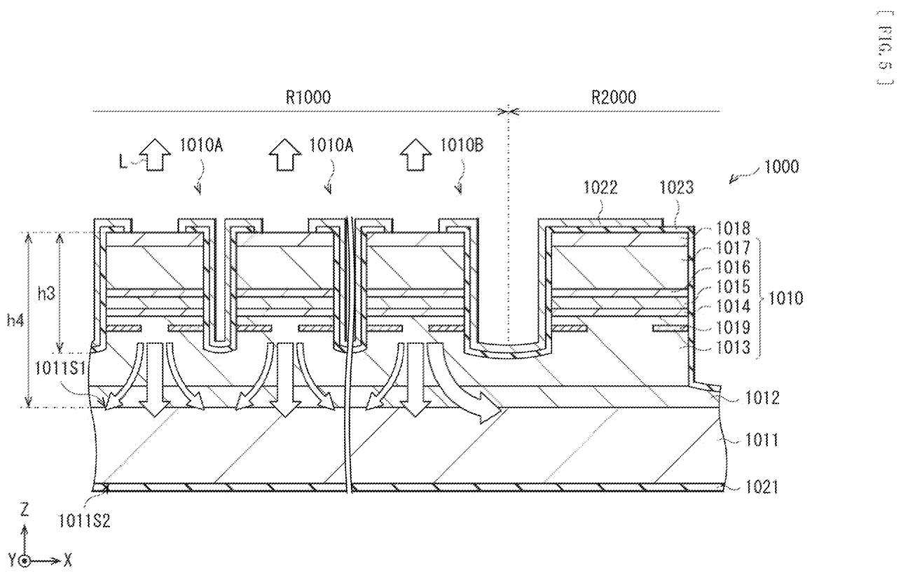

In general, as illustrated in FIG. 5, for example, in a light-emitting element array 1000 having a common electrode 1021 on a back face, base faces of the mesa included in a plurality of light-emitting elements 1010 arrayed in an array section R1000 are formed at a uniform height. The above configuration causes no significant issue to an array with the mesa pitch being wide; in an array with the mesa pitch being narrow, however, as indicated by an arrow in FIG. 5, a light-emitting element 1010A in the center section of the array section R1000, due to an influence of the adjacent light-emitting elements 1010, allows the current to vertically flow toward the common electrode 1021, while a light-emitting element 1010B adjacent to an outer periphery R2000 of the array, due to the adjacent light-emitting elements decreased in number, expands the current, leading to an inclination of decreasing the electric resistance of the light-emitting element. This concentrates the current in the light-emitting element 1010B adjacent to the outer periphery R2000, causing an issue of failing to obtain the uniform light emission in the array.

This issue is also caused to an array in which array pitches of the plurality of light-emitting elements are different. For example, in the high density region in which the array pitch of the plurality of light-emitting elements is narrow, the current vertically flows toward the common electrode of the back face, while in the low density region in which the array pitch of the plurality of light-emitting elements is wide, the current expands as in the light-emitting element 1010B adjacent to the above outer periphery R2000, decreasing the electric resistance of the light-emitting element. This concentrates the current in the light-emitting element in the low density region, failing to obtain the uniform light emission in the array.

In addition, this issue is also caused to, for example, the back face emission-type light-emitting element array that does not have the common electrode on the back face. In the back face emission-type light-emitting element array, the common electrode is formed on the base face of the mesa. In the high density region in which the array pitch of the plurality of light-emitting elements is narrow, the area of the common electrode formed in the base face of the mesa is small, thus increasing the electric resistance of the light-emitting element, while in the low density region in which the array pitch of the plurality of light-emitting elements is wide, the area of the common electrode is large, thus decreasing the electric resistance of the light-emitting element. This concentrates the current in the light-emitting element in the low density region, failing to obtain the uniform light emission in the array.

In contrast, in the present embodiment; in the light-emitting element array 1 in which the plurality of light-emitting elements 10 is arrayed at the mutually different intervals, the recessed sections H (for example, the recessed sections H1 and H2) having the depths different according to the intervals of the plurality of adjacent light-emitting elements 10 are provided. This makes it possible that, in the high density region (for example, the first region R1-1 in which the plurality of light-emitting elements 10 is arrayed at the first pitch l1) in which the array pitch of the plurality of light-emitting elements 10 is narrow, the area of the first electrode 21 formed on the base face of the recessed section H1 between the adjacent light-emitting elements 10 is small; for this reason, though the electric resistance of the light-emitting element 10 is high, the recessed section H1 formed around the light-emitting element 10 is shallow, thus decreasing the electric resistance of the current horizontally flowing in the first contact layer 12 from the first electrode 21 toward the light-emitting element 10. On the other hand, in the low density region (for example, the second region R1-2 in which the plurality of light-emitting elements 10 is arrayed at the second pitch l2) in which the array pitch of the plurality of light-emitting elements 10 is wide, the area of the first electrode 21 formed on the base face of the recessed section H1 between the adjacent light-emitting elements 10 is large; for this reason, though the electric resistance of the light-emitting element 10 is decreased compared with the light-emitting element 10 arrayed in the first region R1-1, the recessed section H2 formed around the light-emitting element 10 is deep, thus increasing the electric resistance of the current horizontally flowing in the first contact layer 12 from the first electrode 21 toward the light-emitting element. This makes it possible to suppress the current concentration to the light-emitting element 10 arrayed at a low density. That is, the electric resistance difference caused by the arraying density of the plurality of light-emitting elements is offset.

The above allows the light-emitting element array 1 of the present embodiment to obtain the light emission substantially uniform in the light-emission region R1.

In addition, in the light-emitting element array 1 of the present embodiment: in the low density region (for example, the second region R1-2) in which the array pitch of the plurality of light-emitting elements 10 is wide, the recessed section H2 forming the mesa form of the light-emitting element 10 is caused to penetrate the first contact layer 12. This decreases the contact area for the first electrode 21 with the first contact layer 12, making it possible to further suppress the current concentration to the light-emitting element 10 arrayed at the low density. For this reason, the above makes it possible to obtain the light emission further substantially uniform in the light-emission region R1.

Next, descriptions will be made of a second embodiment, a modification example, an applicable example, and an applied example of the present disclosure. Hereafter, the same sign is added to a component element similar to that of the first embodiment, and description thereof will be properly omitted.

### 2. Second Embodiment

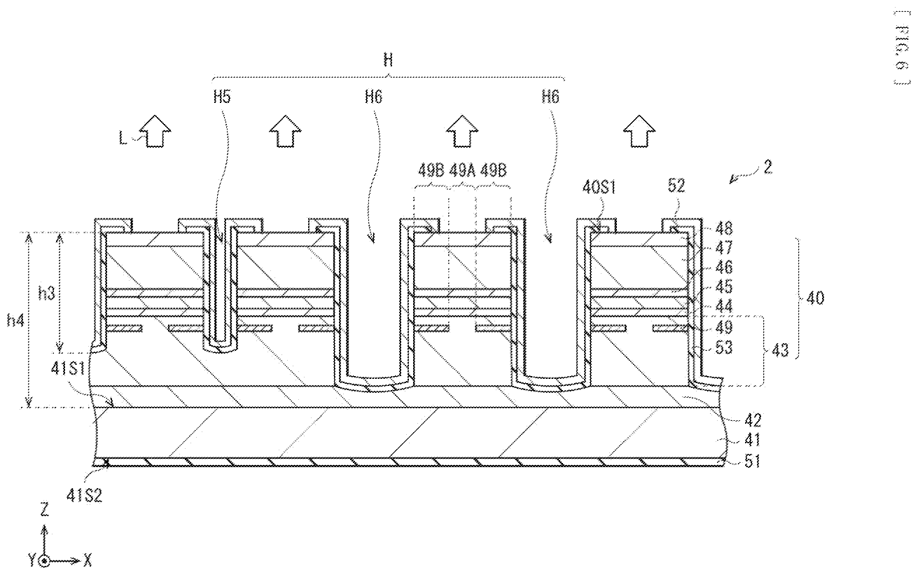

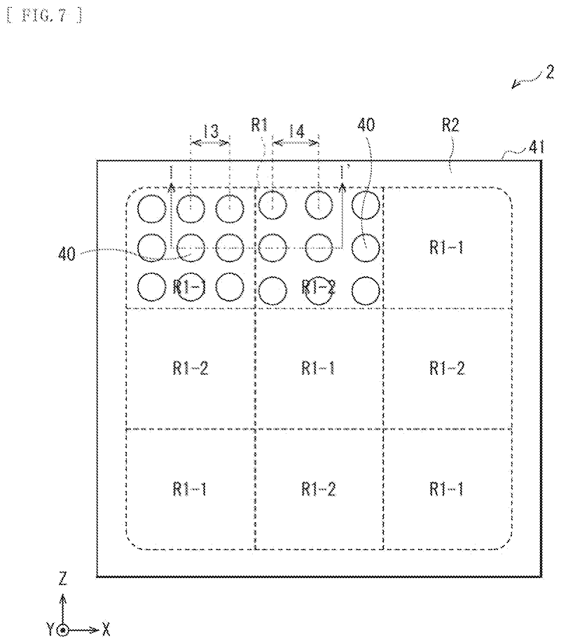

FIG. 6 schematically illustrates one example of a cross-sectional configuration of a light-emitting element array 2 according to a second embodiment of the present disclosure. FIG. 7 schematically illustrates one example of a plan configuration of the overall light-emitting element array 2 illustrated in FIG. 6. FIG. 6 illustrates a cross section that corresponds to the line II-II′ in FIG. 7. In this light-emitting element array 2, surface emission-type VCSELs (Vertical Cavity Surface Emitting LASERs) are integrated in two-dimension array, for example.

### [Configuration of Light-Emitting Element Array]

In the light-emitting element array 2, a plurality of light-emitting elements 40 is arrayed on a surface 41S1 of a substrate having a first face (surface 41S1) and a second face (back face 41S2) that oppose each other, for example. The light-emitting element array 2, similar to the light-emitting element array 1 of the first embodiment, has the light-emission region R1 in which the plurality of light-emitting elements 40 is arrayed in two-dimension array, and the peripheral region R2 provided around the light-emission region R1.

The plurality of light-emitting elements 40 each has the mesa form. The diameter (mesa diameter) of each of the light-emitting elements 40 is slightly smaller than the smallest beam pitch of the laser light outputted from each of the light-emitting elements 40. In a case of making the smallest beam pitch of about 18 μm, for example, the mesa diameter is about 14 μm.

In the light-emitting element array 2, the plurality of light-emitting elements 40, similar to the light-emitting element array 1 of the first embodiment, in the light-emission region R1, is arrayed at mutually different intervals, for example. For example, in the light-emission region R1, as illustrated in FIG. 7, the first region R1-1 in which the plurality of light-emitting elements 40 is arrayed at a first pitch l3 and the second region R1-2 in which the plurality of light-emitting elements 40 is arrayed at a second pitch l4 are alternately arrayed in the matrix direction. Alternatively, the plurality of light-emitting elements 40 may be so randomly arrayed that, in the light-emission region R1, the intervals of the adjacent light-emitting elements 40 are irregularly different.

In addition, the light-emitting element array 2 has the recessed section H with the plurality of light-emitting elements 40 each in the mesa form. This recessed section H has depths different according to the intervals of the plurality of adjacent light-emitting elements 40. For example, when the array pitches (the first pitch l3 and the second pitch l4) of the plurality of light-emitting elements 40 that are respectively arrayed in the first region R1-1 and second region R1-2 illustrated in FIG. 7 has a relation of l3<l4, a depth h3 of a recessed section H5 provided between the adjacent light-emitting elements 40 in the first region R1-1, and a depth h4 of a recessed section H6 provided between the adjacent light-emitting elements 40 in the second region R1-2 have a relation of h3<h4. That is, the light-emitting element array 2 of the present embodiment is such that, around the plurality of light-emitting elements 40 arrayed at mutually different intervals, there are formed the recessed sections H that are shallower as the intervals of the plurality of adjacent light-emitting elements 40 are narrower, and that are deeper as the intervals of the plurality of adjacent light-emitting elements 40 are wider.

In addition, the first pitch l3 and the second pitch l4 are respectively center-to-center distances of the adjacent light-emitting elements 40 in the first region R1-1 and the second region R1-2.

### [Configuration of Light-Emitting Element]

The plurality of light-emitting elements 40 is the VCSEL that outputs the laser light in the layer direction. In the plurality of light-emitting elements 40, there are sequentially layered a first DBR layer 43 including a current confining layer 49 therein, a first spacer layer 44, an active layer 45, a second spacer layer 46, and a second DBR layer 47, for example. Between the plurality of light-emitting elements 40 and a substrate 41, a first contact layer 42 is provided. Upper faces 40S1 of the plurality of light-emitting elements 40 are each provided with a second contact layer 48.

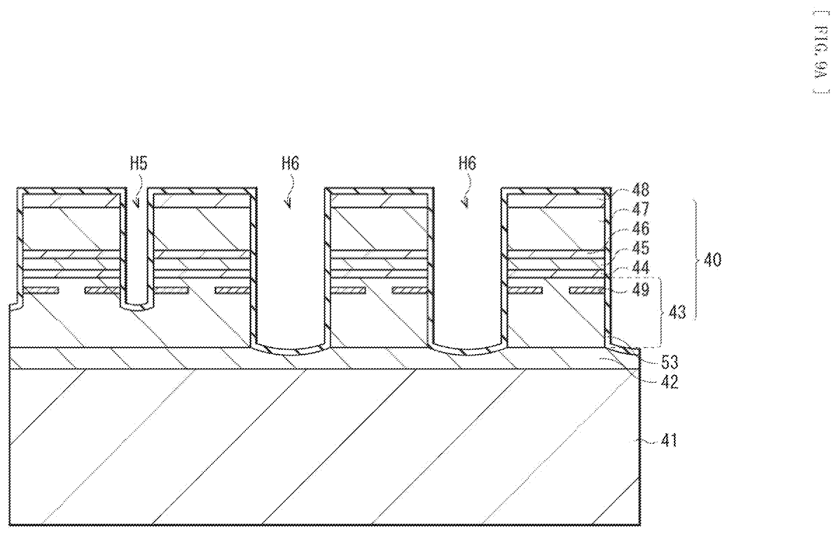

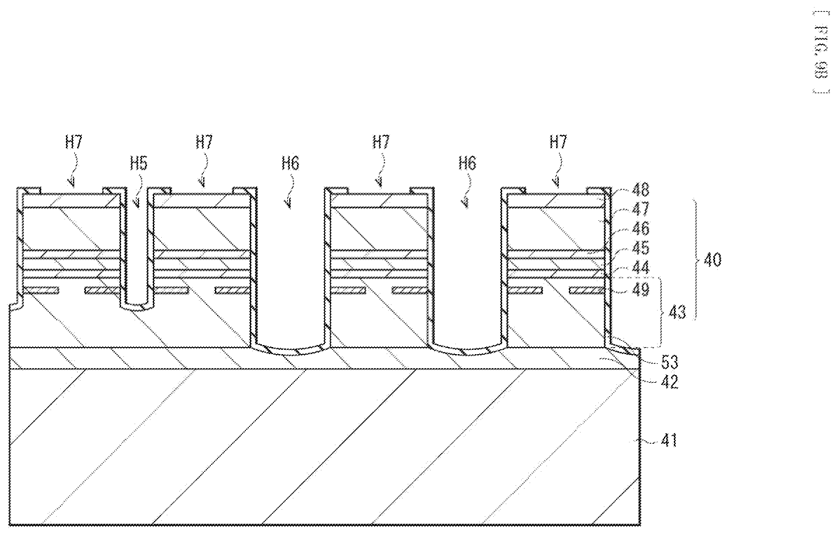

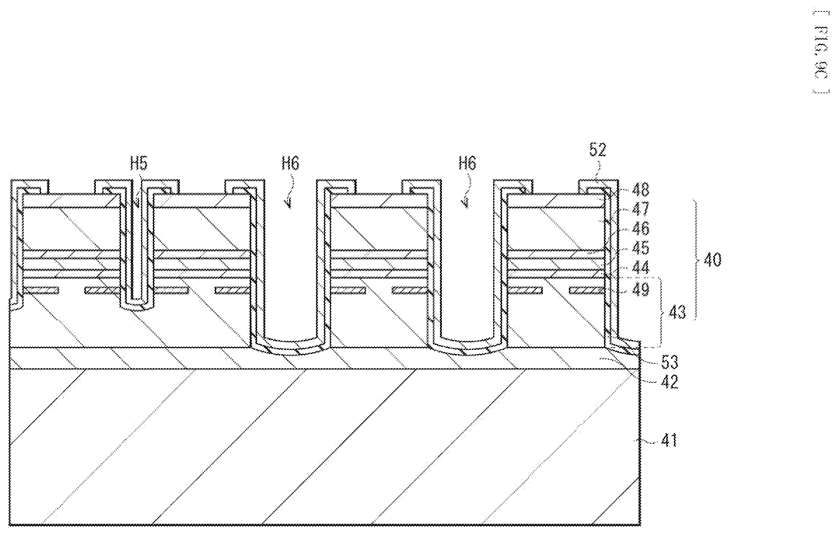

In the present embodiment, a back face 41S2 of the substrate 41, for example, the entire face thereof is provided with a first electrode 51 as a common electrode to the plurality of light-emitting elements 40. For example, the upper face of the first contact layer 42 or first DBR layer 43, the side face of the plurality of light-emitting elements 40, and the upper face of the second contact layer 48 are sequentially covered with an insulative film 53 and the second electrode 52. The insulative film 53 is open on the upper face of the second contact layer 48, and the second electrode 52 is electrically connected via the opening (refer to an opening H7, FIG. 9B) to the second contact layer 48. These points are different from the light-emitting element 10 of the first embodiment, and any configuration other than these is similar to that of the light-emitting element 10.

### [Operation of Light-Emitting Element Array]

In the light-emitting element array 2, applying a predetermined voltage from the laser driver to the first electrode 51 and the second electrode 52 applies a voltage from the first electrode 51 and the second electrode 52 to the respective light-emitting elements 40. This injects the hole from the first electrode 51 and the electron from the second electrode 52 respectively to the active layer 45, generating light derived from the recombining of the electron and the hole. The light generated in the active layer 45 is resonated between the first DBR layer 43 and the second DBR layer 47 thereby to be amplified, outputting the laser light L from the upper face 40S1 of the light-emitting element 40.

### [Manufacturing Method of Light-Emitting Element Array]

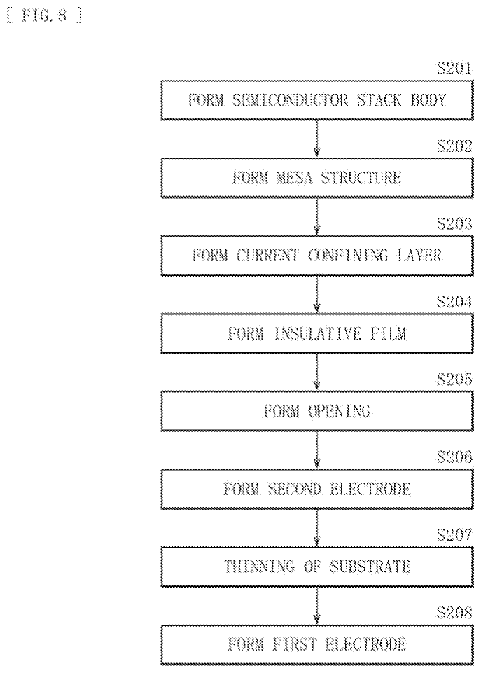

Next, referring to FIG. 8 and FIG. 9A to FIG. 9C, description will be made of a manufacturing method of the light-emitting element array 2.

First, similar to the first embodiment, the process proceeds from step S201 to step S204, and as illustrated in FIG. 9A, the insulative film 53 continuous from the upper face of the second contact layer 48 to the side face and base face of the recessed sections H5 and H6 is formed using, for example, the CVD method or ALD method. Thereafter, as illustrated in FIG. 9B, similar to the first embodiment, the opening H7 is formed at a predetermined position of the insulative film 23 formed on the second contact layer 48 (step S205).

Thereafter, as illustrated in FIG. 9C, the second electrode 52 is formed using the lift off technology, for example, that uses the resist pattern (step S206). Thereafter, thinning of the substrate 41 is performed to a predetermined thickness using the CMP, for example (step S207). Thereafter, the first electrode 51 is formed on the back face 11S2 of the substrate 41 using the CVD method or the ALD method, for example (step S208). The above completes the light-emitting element array 2 illustrated in FIG. 6.

### Workings and Effects

The light-emitting element array 2 of the present embodiment is so made as to form, around the plurality of surface emission-type light-emitting elements 40 arrayed in two-dimension array at the mutually different intervals in the light-emission region R1, the recessed sections H (for example, the recessed sections H5 and H6) that have depths different according to the intervals of the plurality of adjacent light-emitting elements 40.

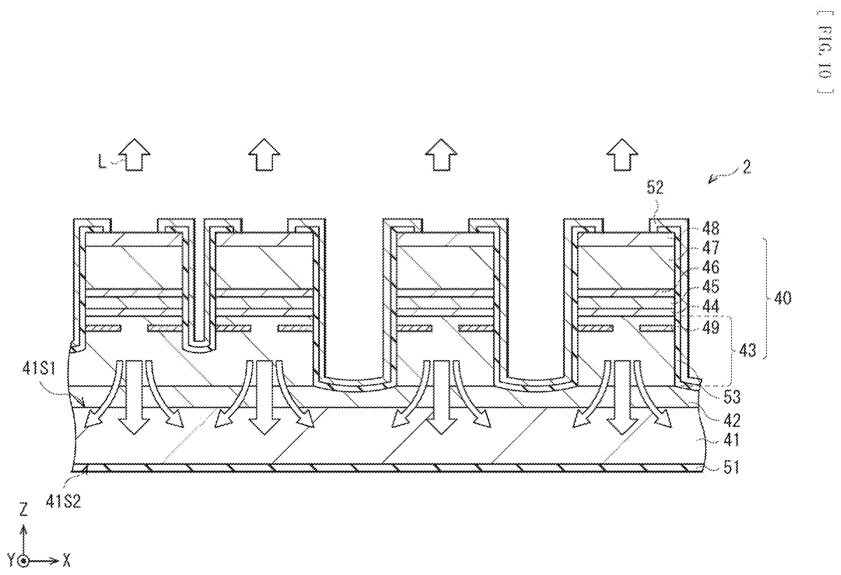

This makes it possible that, in the high density region (for example, the first region R1-1 in which the plurality of light-emitting elements 40 is arrayed at the first pitch l1) in which the array pitch of the plurality of light-emitting elements 40 is narrow, the area of the first electrode 51 corresponding to each of the light-emitting elements 40 is small; for this reason, though the electric resistance of the light-emitting element 40 is high, the recessed section H5 formed around the light-emitting element 40 is shallow, for example, being so formed as to have the base face in the first DBR layer 43, thus decreasing the electric resistance of the current horizontally flowing from the first electrode 51 toward the light-emitting element 40. In the above case, the current path in the light-emitting element is short, thus also decreasing the electric resistance of the current flowing in the light-emitting element 40. On the other hand, in the low density region (for example, the second region R1-2 in which the plurality of light-emitting elements 40 is arrayed at the second pitch l2) in which the array pitch of the plurality of light-emitting elements 40 is wide, the area of the first electrode 51 corresponding to each of the light-emitting elements 40 is large; for this reason, though the electric resistance of the light-emitting element 40 is decreased compared with the light-emitting element 40 arrayed in the first region R1-1, the recessed section H6 formed around the light-emitting element 40 is deep, for example, being so formed as to have the base face in the first contact layer 42, thus increasing the electric resistance of the current horizontally flowing from the first electrode 51 toward the light-emitting element 40. In the above case, the current path in the light-emitting element 40 is long, thus also increasing the electric resistance of the current flowing in the light-emitting element 40. For this reason, as indicated by the arrow illustrated in FIG. 10, for example, the electric resistance difference caused by the arraying density of the plurality of light-emitting elements is offset.

The above allows the light-emitting element array 2 of the present embodiment, similar to the light-emitting element array 2 of the first embodiment, to obtain the light emission substantially uniform in the light-emission region R1.

### 3. Modification Examples

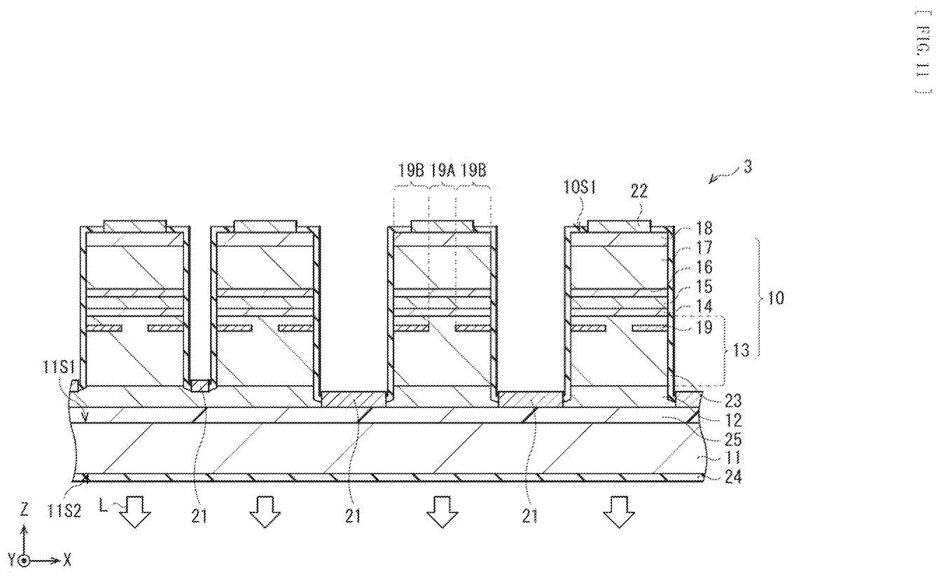

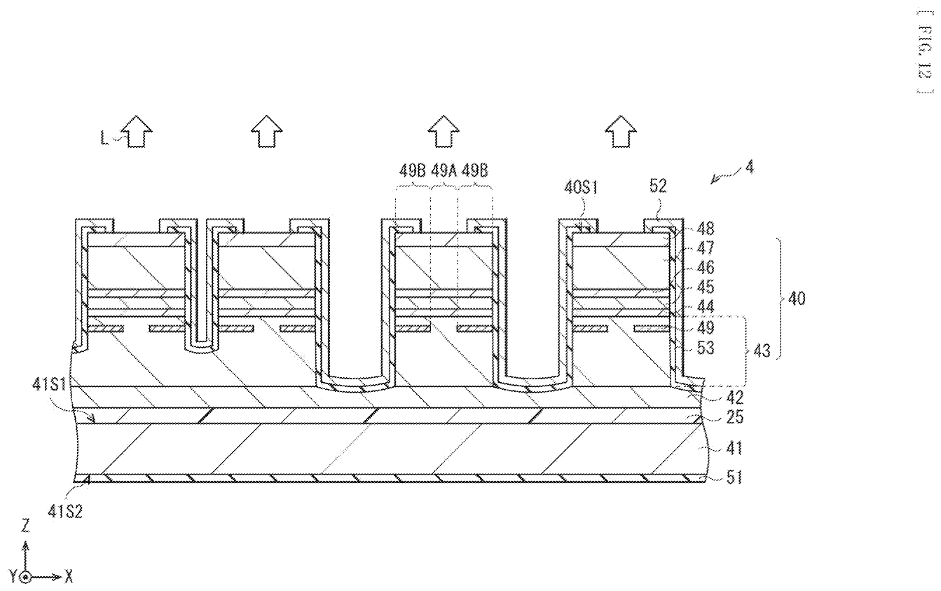

FIG. 11 schematically illustrates one example of a cross-sectional configuration of a light-emitting element array 3 as a modification example of the first embodiment. FIG. 12 schematically illustrates one example of a cross-sectional configuration of a light-emitting element array 4 as a modification example of the second embodiment. From the first and second embodiments, the light-emitting element arrays 3 and 4 of the present modification examples are different in providing a current diffusion adjusting layer 25 between the substrate 11 and the first contact layer 12 and between the substrate 41 and the first contact layer 42, respectively.

The current diffusion adjusting layer 25 adjusts a change amount that changes according to the depth of the recessed section H and that is of the electric resistance of the current horizontally flowing from the first electrode 21 or the first electrode 51 to the respective light-emitting elements. The current diffusion adjusting layer 25 is so configured as to be lower in carrier concentration than the first contact layers 12 and 42. In addition, the current diffusion adjusting layer 25 may be so made as to modulate the carrier concentration in the layer direction (for example, Z-axis direction). For example, the carrier concentration may be so made as to be gradually higher from the substrate 11 side toward the first contact layer 12.

As described above; in the light-emitting element arrays 3 and 4 of the present modification examples, the current diffusion adjusting layer 25 is provided between the substrate 11 and the first contact layer 12 and between the substrate 41 and the first contact layer 42, respectively. This makes it possible to control an adjusting width of the current resistance, making it possible to further offset the electric resistance difference caused by the arraying density of the plurality of light-emitting elements 10 or 40. The above makes it possible to obtain the light emission further substantially uniform in the light-emission region R1.

In addition, modulating, as described above, for example, the concentration of the carrier included in the current diffusion adjusting layer 25 makes it possible to freely control the adjusting width of the current resistance.

In addition, the example has been described that, in the light-emitting element array 4 illustrated in FIG. 12, the current diffusion adjusting layer 25 is provided between the substrate 41 and the first contact layer 42; the present disclosure is, however, not limited to this. The current diffusion adjusting layer 25 may be provided between the first contact layer 42 and the first DBR layer 43, for example. In the above case as well, it is possible to obtain the similar effect.

### 4. Applicable Example

The present technique is applicable to various electronic devices including a semiconductor laser. The present technique is applicable a light source provided in a mobile electronic device such as a smartphone or light sources of various sensing devices that detect the shape, operation, or the like.

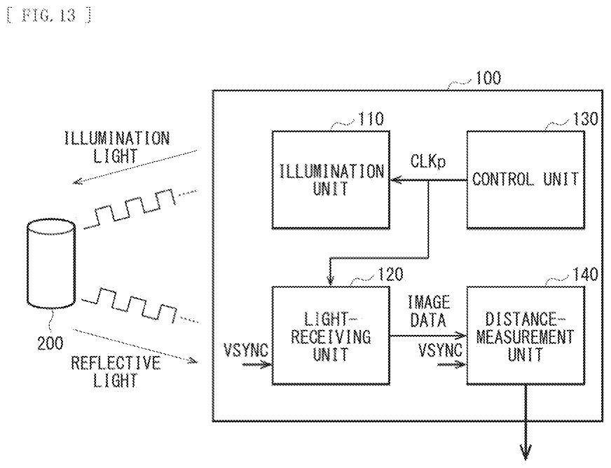

FIG. 13 is a block diagram illustrating a schematic configuration of a distance-measurement unit (distance-measurement unit 100) that uses an illumination unit 110 provided with the above light-emitting element arrays (for example, the light-emitting element array 1). The distance-measurement unit 100 measures the distance by the ToF method. The distance-measurement unit 100 has the illumination unit 110, a light-receiving unit 120, a control unit 130, and a distance-measurement unit 140, for example.

The illumination unit 110 has, as a light source, the light-emitting element array 1 illustrated FIG. 1 or the like, for example. The illumination unit 110 generates illumination light synchronously with, for example, a rectangular-wave light-emitting control signal CLKp. In addition, as long as being a cycle signal, the light-emitting control signal CLKp is not limited to the rectangular wave. The light-emitting control signal CLKp may be a sine wave, for example.

The light-receiving unit 120 receives reflected light reflected from a to-be-irradiated object 200, and every time the cycle of a vertical synchronous signal VSYNC elapses, detects the received light amount in the cycle. A cycle signal of 60 hertz (Hz), for example, is used as the vertical synchronous signal VSYNC. Further, in the light-receiving unit 120, a plurality of pixel circuits is arrayed in two-dimension grating. To the distance-measurement unit 140, the light-receiving unit 120 supplies the image data (frame) that accords to the received light amount of these pixel circuits. It should be noted that the frequency of the vertical synchronous signal VSYNC is not limited to 60 hertz (Hz), and 30 hertz (Hz) or 120 hertz (Hz) is acceptable.

The control unit 130 controls the illumination unit 110. The control unit 130 generates the light-emitting control signal CLKp and supplies the light-emitting control signal CLKp to the illumination unit 110 and the light-receiving unit 120. The frequency of the light-emitting control signal CLKp is 20 mega hertz (MHz), for example. It should be noted that the frequency of the light-emitting control signal CLKp is not limited to 20 mega hertz (MHz), and 5 mega hertz (MHz), for example, is acceptable.

On the basis of the image data, the distance-measurement unit 140 measures, by the ToF method, the distance to the to-be-irradiated object 200. This distance-measurement unit 140 measures the distance per pixel circuit, and generates, per pixel, a depth map that indicates, by a harmony value, the distance to the object. This depth map is used for the image processing that performs an airbrushing of the level that accords to the distance or for the automatic focus (AF) processing that, according to the distance, seeks the focal point of the focus lens.

### 5. Applied Example

### (Example Applied to Mobile Body)

The technique according to the present disclosure (the present technique) is applied to various products. The technique according to the present disclosure may be realized as a device installed on any type of mobile bodies including an automobile, an electric vehicle, a hybrid electric vehicle, a motorcycle, a bicycle, a personal mobility, an airplane, a drone, a ship, and a robot, for example.

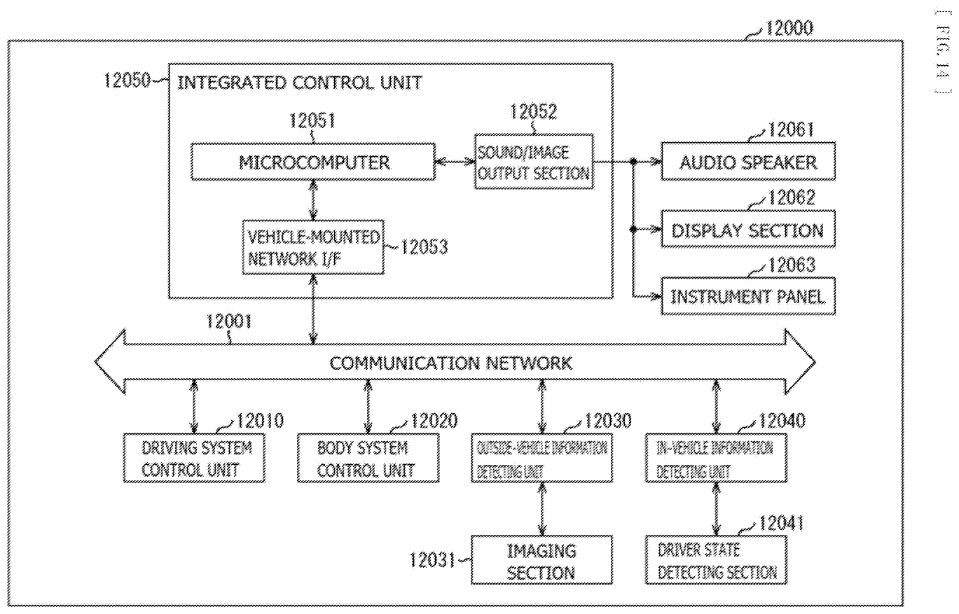

FIG. 14 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up display.

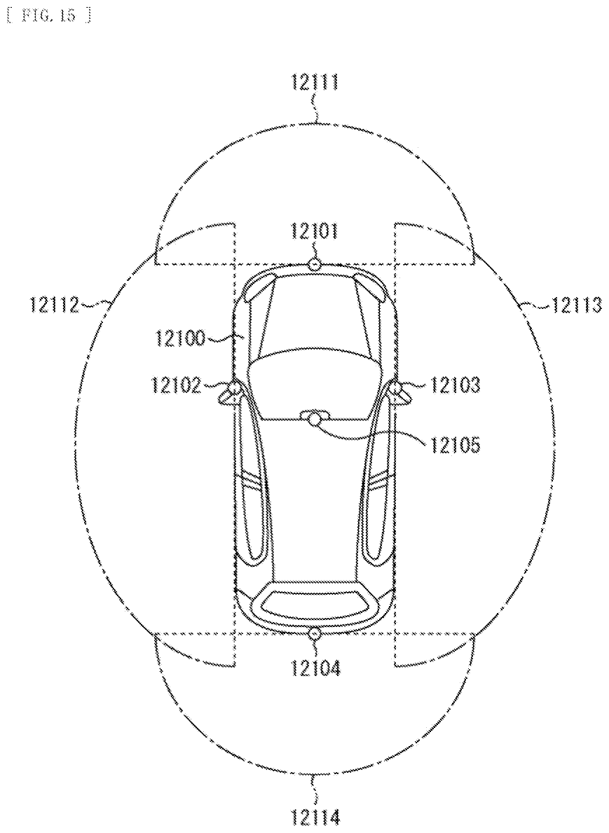

FIG. 15 is a diagram depicting an example of the installation position of the imaging section 12031.

In FIG. 15, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 15 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example. At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has explained about the one example of a mobile body control system to which the technique according to the present disclosure is applicable. The technique according to the present disclosure is applicable to the imaging section 12031 of the configurations described above. Specifically, the light-emitting element array 1 is applicable to the imaging section 12031. Applying, to the imaging section 12031, the technique according to the present disclosure makes it possible to perform, in the mobile body control system, a high-accuracy controlling that uses a captured image.

The above description has explained about the present technique by raising the first embodiment, the second embodiment, the modification example, the applicable example and the applied example; the present technique is, however, not limited to the above embodiments and the like, and may be subjected to various modifications. For example, a layer configuration of the light-emitting element 10 described in the above embodiments is one example, and any other layer may be further provided. In addition, the material of each of the layers is one example, and is not limited to those described above.

In addition, the effects described in the present specification is merely an exemplification and is not limit, and any other effect may be attained.

In addition, the present technique may be configured as follows. The present technique having the configuration below sequentially layers to form, on the substrate, the plurality of compound semiconductor layers included in the light-emitting element, thereafter, forms, on the compound semiconductor layers, the resist layer that has the patterns different in density, and performs, with the resist layer as the mask, the reactive ion etching under a condition of 80° C. or less. This makes it possible that the plurality of light-emitting elements having the mesa form is, on the first face, formed in two-dimension array at the mutually different intervals, and between the plurality of adjacent light-emitting elements, the recessed sections that have depths different according to the intervals of the plurality of adjacent light-emitting elements are formed. The above offsets the electric resistance difference caused by the arraying density of the plurality of light-emitting elements, making it possible to obtain the light emission substantially uniform in the face.

(1)

A light-emitting element array including: a substrate that has a first face and a second face that oppose each other; a plurality of light-emitting elements arrayed in two-dimension array on the first face at mutually different intervals, each of the light-emitting elements having a mesa form; and recessed sections that are provided around the plurality of light-emitting elements, have the mesa form, and have depths different according to the intervals of the plurality of light-emitting elements adjacent to each other.

(2)

The light-emitting element array according to the (1), in which the depths of the recessed sections are shallower as the intervals of the plurality of adjacent light-emitting elements are narrower, and the depths of the recessed sections are deeper as the intervals of the plurality of adjacent light-emitting elements are wider.

(3)

The light-emitting element array according to the (1) or (2), in which the substrate further has an array section where the plurality of light-emitting elements is provided in the two-dimension array, and the array section has a plurality of regions, and the plurality of light-emitting elements is arrayed at the intervals different per a region of the regions.

(4)

The light-emitting element array according to the (1) or (2), in which the substrate further has an array section where the plurality of light-emitting elements is provided in the two-dimension array, and the plurality of light-emitting elements is randomly arrayed in the array section.

(5)

The light-emitting element array according to any one of the (1) to (4), in which a light-emitting element of the light-emitting elements has a first light reflective layer, an active layer, and a second light reflective layer that are sequentially layered from the first face side of the substrate, and the light-emitting element further has a first contact layer provided between the first light reflective layer and the substrate, and a second contact layer on a side of a face, of the second light reflective layer, that is opposite to the active layer

(6)

The light-emitting element array according to the (5), in which the light-emitting element further has a first electrode provided on a base section of a recessed section of the recessed sections, and a second electrode provided on the second contact layer.

(7)

The light-emitting element array according to the (5) or (6), in which the light-emitting element includes a back face emission-type face emission laser that outputs a laser light from the second face.

(8)

The light-emitting element array according to any one of the (5) to (7), in which the recessed sections have a first recessed section provided between the plurality of adjacent light-emitting elements arrayed at a first interval, and a second recessed section provided between the plurality of adjacent light-emitting elements arrayed at a second interval wider than the first interval, and the first recessed section has a base face in the first contact layer, and the second recessed section penetrates the first contact layer.

(9)

The light-emitting element array according to the (8), further including: between the substrate and the first contact layer, a current diffusion adjusting layer lower in carrier concentration than the first contact layer.

(10)

The light-emitting element array according to the (9), in which the current diffusion adjusting layer changes in the carrier concentration from the substrate toward the first contact layer.

(11)

The light-emitting element array according to the (5), in which the light-emitting element further has a first electrode provided on the second face side of the substrate, and a second electrode provided on the second contact layer.

(12)

The light-emitting element array according to the (11), in which the first electrode includes a common electrode to the plurality of light-emitting elements.

(13)

The light-emitting element array according to the (5), (11), or (12), in which the light-emitting element includes a surface emission-type face emission laser that outputs a laser light from the second contact layer side.

(14)

The light-emitting element array according to any one of the (5) or (11) to (13), in which the recessed sections have a first recessed section provided between the plurality of adjacent light-emitting elements arrayed at a first interval, and a second recessed section provided between the plurality of adjacent light-emitting elements arrayed at a second interval wider than the first interval, and the first recessed section has a base face in the first light reflective layer, and the second recessed section penetrates the first light reflective layer.

(15)

The light-emitting element array according to the (13) or (14), further including a current diffusion adjusting layer provided between the substrate and the first contact layer or between the first contact layer and the first light reflective layer.

(16)

The light-emitting element array according to the (15), in which the current diffusion adjusting layer changes in carrier concentration from the substrate toward the first light reflective layer.

(17)

A manufacturing method of a light-emitting element array, the method including: sequentially layering to form, on a substrate, a plurality of compound semiconductor layers included in a light-emitting element; forming, on the compound semiconductor layers, a resist layer that has patterns different in density; and forming, in the compound semiconductor layers, recessed sections that have depths different according to a pattern density of the resist layer by performing, with the resist layer as a mask, a reactive ion etching under a condition of 80° C. or less.

The present application claims the benefit of Japanese Priority Patent Application JP2021-140414 filed with the Japan Patent Office on Aug. 30, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light-emitting element array comprising:
a substrate that has a first face and a second face that oppose each other;
a plurality of light-emitting elements arrayed in two-dimension array on the first face at mutually different intervals, each of the light-emitting elements having a mesa form; and
recessed sections that are provided around the plurality of light-emitting elements, have the mesa form, and have depths different according to the intervals of the plurality of light-emitting elements adjacent to each other.

2. The light-emitting element array according to claim 1, wherein the depths of the recessed sections are shallower as the intervals of the plurality of adjacent light-emitting elements are narrower, and the depths of the recessed sections are deeper as the intervals of the plurality of adjacent light-emitting elements are wider.

3. The light-emitting element array according to claim 1, wherein the substrate further has an array section where the plurality of light-emitting elements is provided in the two-dimension array, and
the array section has a plurality of regions, and the plurality of light-emitting elements is arrayed at the intervals different per a region of the regions.

4. The light-emitting element array according to claim 1, wherein the substrate further has an array section where the plurality of light-emitting elements is provided in the two-dimension array, and
the plurality of light-emitting elements is randomly arrayed in the array section.

5. The light-emitting element array according to claim 1, wherein a light-emitting element of the light-emitting elements has a first light reflective layer, an active layer, and a second light reflective layer that are sequentially layered from the first face side of the substrate, and
the light-emitting element further has a first contact layer provided between the first light reflective layer and the substrate, and a second contact layer on a side of a face, of the second light reflective layer, that is opposite to the active layer.

6. The light-emitting element array according to claim 5, wherein the light-emitting element further has a first electrode provided on a base section of a recessed section of the recessed sections, and a second electrode provided on the second contact layer.

7. The light-emitting element array according to claim 5, wherein the light-emitting element comprises a back face emission-type face emission laser that outputs laser light from the second face.

8. The light-emitting element array according to claim 5, wherein the recessed sections have a first recessed section provided between the plurality of adjacent light-emitting elements arrayed at a first interval, and
a second recessed section provided between the plurality of adjacent light-emitting elements arrayed at a second interval wider than the first interval, and the first recessed section has a base face in the first contact layer, and the second recessed section penetrates the first contact layer.

9. The light-emitting element array according to claim 8, further comprising: between the substrate and the first contact layer, a current diffusion adjusting layer lower in carrier concentration than the first contact layer.

10. The light-emitting element array according to claim 9, wherein the current diffusion adjusting layer changes in the carrier concentration from the substrate toward the first contact layer.

11. The light-emitting element array according to claim 5, wherein the light-emitting element further has a first electrode provided on the second face side of the substrate, and a second electrode provided on the second contact layer.

12. The light-emitting element array according to claim 11, wherein the first electrode comprises a common electrode to the plurality of light-emitting elements.

13. The light-emitting element array according to claim 5, wherein the light-emitting element comprises a surface emission-type face emission laser that outputs laser light from the second contact layer side.

14. The light-emitting element array according to claim 5, wherein the recessed sections have a first recessed section provided between the plurality of adjacent light-emitting elements arrayed at a first interval, and a second recessed section provided between the plurality of adjacent light-emitting elements arrayed at a second interval wider than the first interval, and
the first recessed section has a base face in the first light reflective layer, and the second recessed section penetrates the first light reflective layer.

15. The light-emitting element array according to claim 13, further comprising a current diffusion adjusting layer provided between the substrate and the first contact layer or between the first contact layer and the first light reflective layer.

16. The light-emitting element array according to claim 15, wherein the current diffusion adjusting layer changes in carrier concentration from the substrate toward the first light reflective layer.

17. A manufacturing method of a light-emitting element array, the method comprising:
sequentially layering to form, on a substrate, a plurality of compound semiconductor layers included in a light-emitting element;
forming, on the compound semiconductor layers, a resist layer that has patterns different in density; and
forming, in the compound semiconductor layers, recessed sections that have depths different according to a pattern density of the resist layer by performing, with the resist layer as a mask, a reactive ion etching under a condition of 80° C. or less.
